(19) United States
(12) Patent Application Publication
(10) Pub. No.: US 2005/0100066 A1
(43) Pub. Date: May 12, 2005

(54) High temperature laser diode

(76) Inventor: Benoit Reid, Ottawa (CA)

Correspondence Address: STIKEMAN ELLIOTT, 1600-50 O'CONNOR STREET, OTTAWA, ON, KIP LS2, CA

(21) Appl. No.: 10/981,665

(22) Filed: Nov. 5, 2004

Related U.S. Application Data
(60) Provisional application No. 60/517,400, filed on Nov. 6, 2003.

(51) Int. Cl. H01S 5/00

(52) U.S. Cl. 372/43; 372/44; 372/45

(57) ABSTRACT

A semiconductor laser structure having confinement layers to confine electrons to an active region (quantum wells) and having separate antimonide-based cladding layers to provide additional electron confinement and photon confinement is suited to high temperature operation. The structure is suitable for lasing across telecommunications wavelengths from 980 nm to 1.55 μm (microns). The cladding layer uses AlAsSb which can be lattice-matched to InP and can be used to achieve large conduction band offsets. It is very useful for coolerless (without thermo-electric cooler) operation.

### CROSS REFERENCE TO RELATED APPLICATIONS

This application claims priority from U.S. Provisional Patent application Ser. No. 60/517,400 filed Nov. 6, 2003.

### MICROFICHE APPENDIX

Not Applicable.

### TECHNICAL FIELD

The present invention relates to semiconductor laser diodes and in particular, to a semiconductor laser diode which has excellent temperature characteristics.

### BACKGROUND OF THE INVENTION

Semiconductor laser diodes can be divided into two groups, those for use in short wavelength applications (λ=0.78-0.89 μm) (1 μm=1 micron) and those for use in long wavelength applications (λ=0.98-1.6 μm). Gallium arsenide (GaAs) based material systems are well suited to short wavelength applications and present excellent high temperature performance but they are generally not suited to applications beyond about 1.2 μm. However, modern optical telecommunications systems operate at long wavelengths, typically 980 nm to 1.55 μm and thus indium-phosphide (InP) based materials are typically used because they are better suited to long wavelength applications, especially at 1.3 to 1.6 μm, which is the typical signal transmission wavelength range. InP material systems usually exhibit poor high temperature performance, thus in order to operate InP based devices reliably, external cooling is usually required. It is well known in the art to package semiconductor laser diodes with integral thermoelectric coolers which increase cost, complexity and power dissipation.

Generally, the high temperature operation capability of laser diodes is assessed through the use of a characteristic temperature T₀, linking threshold currents and temperature operation as summarized in Equation (1) below:
I=I₀ exp(T/T₀) (1)

Where I is the threshold current, I₀ is a scaling factor and T is a temperature in degrees Kelvin (° K). Therefore, higher T₀ permits higher temperature operation because for higher T₀, the threshold current varies less with temperature. Higher T₀ has been linked to larger conduction band offsets. Conversely, the poor temperature performance in typical InP material systems is usually attributed to the small conduction band offset, which is also often due to the lack of a suitable available material with a higher energy bandgap and a lower index of refraction than InP.

A first example of a known InP based laser structure is shown in FIG. 1. This laser uses the InGaAsP/InP material system which usually has a poor characteristic temperature of T₀≈60 K. Referring to FIG. 1, the laser structure 100 comprises cladding layer 101 of p-InP, confinement layers 102, 108 and barrier layers 104, 106 of InGaAsP (indium-gallium-arsenide-phosphide), and quantum wells 103, 105, 107 also of InGaAsP but of a different composition than the barrier layers and confinement layers, and another cladding layer 109 of n-InP. (Note that in the figures, an asterisk is used to represent a different composition of the same material.)

Referring to the band diagram of FIG. 1, the conduction band offset 110 between the cladding layers (101, 109) and the confinement layers (102, 108) is 109 meV. (Note that in the figures, these values are displayed in parentheses in units of eV (electron Volts) to avoid ambiguity with the reference numbers). The conduction band offset 111 between the barrier and confinement layers (102, 104, 106, 108) and the quantum wells (103, 105, 107) is 111 meV. The valence band offset 112 between the cladding layers (101, 109) and the confinement layers (102,108) is 164 meV. The valence band offset 113 between the barrier and confinement layers (102, 104, 106, 108) and the quantum wells (103, 105, 107) is 166 meV. The energy bandgap 114 of InP (101, 109) is 1.35 eV. Referring now to the index of refraction diagram of FIG. 1, for an optical wavelength of 1.55 μm, the index of refraction of the cladding layers (101, 109) is 3.17, the index of refraction of the barrier and confinement layers (102, 104, 106, 108) is 3.31 and the index of refraction of the quantum wells (103, 105, 107) is 3.6. (Note that in the figures, these values are displayed in parentheses to avoid ambiguity with the reference numbers).

A second example of a known InP based laser structure is shown in FIG. 2. This laser uses the InGaAlAs/InP material system and has a better characteristic temperature of T₀≈90 K than the structure of the first example. Referring to FIG. 2, the laser structure 200 comprises connection layer 201 of p-InP, cladding layers 202, 210 of InAlAs (indium-aluminide-arsenide), confinement layers 203, 209 and barrier layers 205, 207 of InGaAlAs, and quantum wells 204, 206, 208 of InGaAlAs (indium-gallium-aluminide-arsenide) but of a different composition than the confinement and barrier layers 203, 205, 207, 209, and a substrate layer 211 of n-InP. Note that in general, semiconductor laser diodes are constructed on a substrate (211 in FIG. 2) and have a connection layer (210 in FIG. 2) for connecting to the external world. The connection and substrate layers are illustrated in FIG. 2 for completeness but these layers do not play a significant role in the structure in terms of optical and electrical confinement and are therefore not illustrated in the other figures for brevity. Referring to the band diagram of FIG. 2, the conduction band offset 212 between the connection and substrate layers (201, 211) and the cladding layers (202, 210) is −185 meV. The conduction band offset 213 between cladding layers (202, 210) and the confinement and barrier layers (203, 205, 207, 209) is 297 meV. The conduction band offset 214 between the confinement and barrier layers (203, 205, 207, 209) and the quantum wells (204, 206, 208) is 165 meV. The valence band offset 215 between the connection and substrate layers (201, 211) and the cladding layers (202, 210) is 75 meV. The conduction band offset 216 between cladding layers (202, 210) and the confinement and barrier layers (203, 205, 207, 209) is 127 meV. The conduction band offset 217 between the confinement and barrier layers (203, 205, 207, 209) and the quantum wells (204, 206, 208) is 71 meV. The energy bandgap 218 of InP (201, 211) is 1.35 eV and the energy bandgap 219 of InAlAs (202, 210) is 1.46 eV. Referring now to the index of refraction diagram of FIG. 2, for an optical wavelength of 1.55 μm, the index of refraction of the connection and substrate layers (201, 211) is 3.17, the index of refraction of the cladding layers (202, 210) is 3.2, the index of refraction of the confinement and barrier layers (203, 205, 207, 209) is 3.35 and the index of refraction of the quantum wells (204, 206, 208) is 3.6.

Another example of a known laser structure is shown in FIG. 3. This laser differs from the first two examples in that it is based on GaAs. It uses the InGaNAs/GaAs material system (indium-gallium-nitride-arsenide/gallium-arsenide) and has an improved characteristic temperature of T₀≈120 K than the structures of the first two examples. However, it is not necessarily suitable or desirable to use the GaAs system, especially for optical telecommunications wavelengths. Referring to FIG. 3, the laser structure 300 comprises cladding layer 301 of p-AlGaAs, confinement layers 302, 308 and barrier layers 304, 306 of GaAs, and quantum wells 303, 305, 307 of GaInNAs and another cladding layer 309 of n-AlGaAs. Referring to the band diagram of FIG. 3, the conduction band offset 310 between the cladding layers (301, 309) and the confinement layers (302, 308) is 224 meV. The conduction band offset 311 between the confinement and barrier layers (302, 304, 306, 308) and the quantum wells (303, 305, 307) is 434 meV. The valence band offset 312 between the cladding layers (301, 309) and the confinement layers (302, 308) is 150 meV. The valence band offset 313 between the confinement and barrier layers (302, 304, 306, 308) and the quantum wells (303, 305, 307) is 186 meV. The energy bandgap 314 of AlGaAs (301, 309) is about 1.90 eV and the energy bandgap 315 of GaAs (302, 304, 306, 308) is 1.52 eV. Referring now to the index of refraction diagram of FIG. 3, for an optical wavelength of 1.55 μm, the index of refraction of the cladding layers (301, 309) is 3.26, the index of refraction of the confinement and barrier layers (302, 304, 306, 308) is 3.40 and the index of refraction of the quantum wells (303, 305, 307) is 3.6. Note that the structure of FIG. 3 would in practice be sandwiched between a n-GaAs substrate and a pGaAs connection layer for mechanical and electrical connection to the external world.

The above described prior art laser structures have poor temperature performance or other disadvantages. Accordingly, a semiconductor laser structure for optical telecommunications wavelengths, capable of improved high temperature operation remains highly desirable.

### SUMMARY OF THE INVENTION

It is therefore an object of the present invention to provide an improved semiconductor laser structure, capable of high temperature operation.

Accordingly, an aspect of the present invention provides a semiconductor laser structure having an active region, a confinement layer adjacent to the active region and a cladding layer adjacent to the confinement layer. The active region is capable of emitting radiation, and is constructed of antimony-free material. The confinement layer is adapted to confine electrons in the active region, and is constructed of antimony-free material. The cladding layer comprises an antimony-based (Sb) alloy.

In some embodiments, the cladding layer has a lower index of refraction than the confinement layer.

In some embodiments, the cladding layer has a larger bandgap than the confinement layer.

In other embodiments, the cladding layer is lattice-matched to InP.

In some embodiments, the cladding layer comprises AlAsSb.

In other embodiments, the cladding layer comprises a compound comprising predominantly Al, As and Sb.

In still other embodiments, the cladding layer comprises AlGaAsSb.

In some embodiments, the active region comprises at least one quantum well and in other embodiments, the active region comprises a plurality of quantum wells separated by barrier layers.

In some embodiments, the barrier layers comprise the same material as the confinement layer.

In some embodiments, the quantum well(s) comprises InGaAsP.

In some embodiments, the confinement layer comprises InP.

In other embodiments, the quantum well(s) comprises InGaAlAs.

In some embodiments, the confinement layer comprises InAlAs.

In some embodiments, the active region is adapted to emit radiation at a wavelength of about 980 nm.

In other embodiments, the active region is adapted to emit radiation at a wavelength of about 1.3 μm

In still other embodiments, the active region is adapted to emit radiation at a wavelength of about 1.55 μm

In some embodiments, the laser structure comprises a Fabry-Perot laser.

In other embodiments, the laser structure comprises a distributed feedback (DFB) laser.

In still other embodiments, the laser structure comprises a semiconductor optical amplifier (SOA).

According to another aspect of the present invention, there is provided a semiconductor laser structure having an active region having a first side and a second side, the active region being capable of emitting radiation, a first confinement layer adjacent the first side of said active region, the first confinement layer adapted to confine electrons in the active region, a second confinement layer adjacent the second side of the active region, the second confinement layer adapted to confine electrons in the active region, a first cladding layer adjacent the first confinement layer, the first cladding layer comprising an antimony-based (Sb) alloy; and a second cladding layer adjacent the second confinement layer, the second cladding layer comprising an antimony-based (Sb) alloy.

In some embodiments, the first confinement layer and the second confinement layer cooperate to confine electrons in the active region.

In some embodiments, the first cladding layer and the second cladding layer are adapted to confine electrons in the active region.

In some embodiments, the first cladding layer and the second cladding layer are adapted to cooperate with the first confinement layer and the second confinement layer to confine electrons in the active region.

In some embodiments, the first cladding layer and the second cladding layer are lattice-matched to InP.

In some embodiments, the first cladding layer and the second cladding layer comprise AlAsSb.

In other embodiments, the first cladding layer and the second cladding layer comprise a compound comprising predominantly Al, As and Sb.

In some embodiments, the first cladding layer and said second cladding layer comprise AlGaAsSb.

In some embodiments, the active region comprises at least one quantum well.

In some embodiments, the first confinement layer and the second confinement layer comprise InP.

In other embodiments, the quantum well(s) comprise InGaAsP.

In some embodiments, the first confinement layer and said second confinement layer comprise InAlAs.

In other embodiments, the quantum well(s) comprise InGaAlAs.

In still other embodiments, the active region comprises at least one quantum well, the quantum well(s) comprise InGaAlAs, the first confinement layer and the second confinement layer comprise InAlAs, and the active region is adapted to emit radiation at a wavelength of about 980 nm.

According to another aspect of the present invention, there is provided a semiconductor laser structure based on an InP material system and having an active region capable of emitting radiation; a confinement layer adjacent the active region, the confinement layer adapted to confine electrons in the active region; and a cladding layer adjacent the confinement layer, the cladding layer comprising an antimony-based (Sb) alloy.

The laser structure can operate at high temperatures and is very useful for coolerless operation required for low power dissipation in optical systems.

### BRIEF DESCRIPTION OF THE DRAWINGS

Further features and advantages of the present invention will become apparent from the following detailed description, taken in combination with the appended drawings, in which:

FIG. 1 is a diagram showing the band structure and index of refraction characteristics of a first prior art InP-based laser structure;

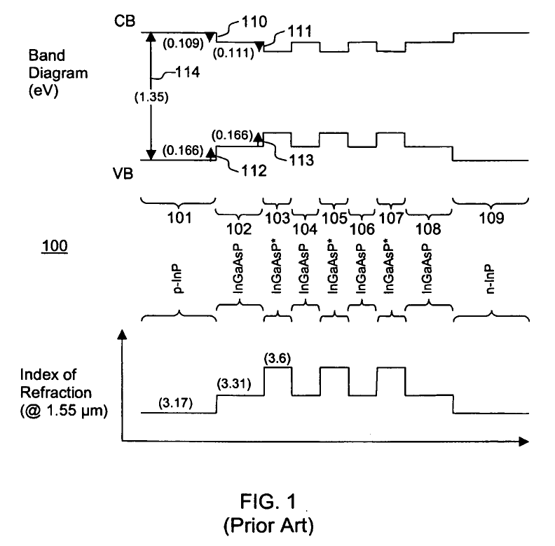

FIG. 2 is a diagram showing the band structure and index of refraction characteristics of a second prior art InP-based laser structure;

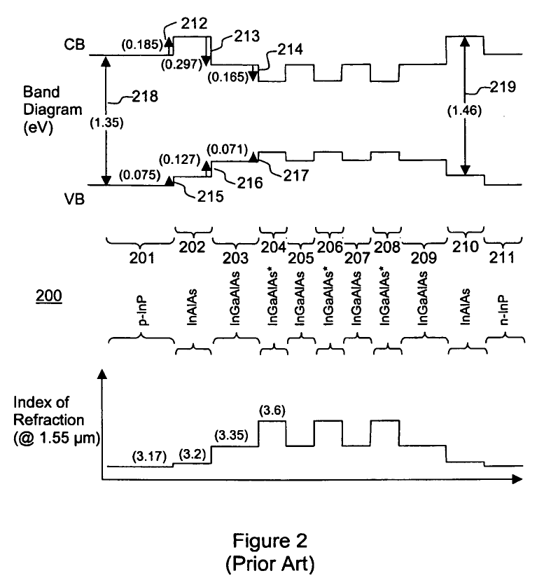

FIG. 3 is a diagram showing the band structure and index of refraction characteristics of a prior art GaAs-based laser structure;

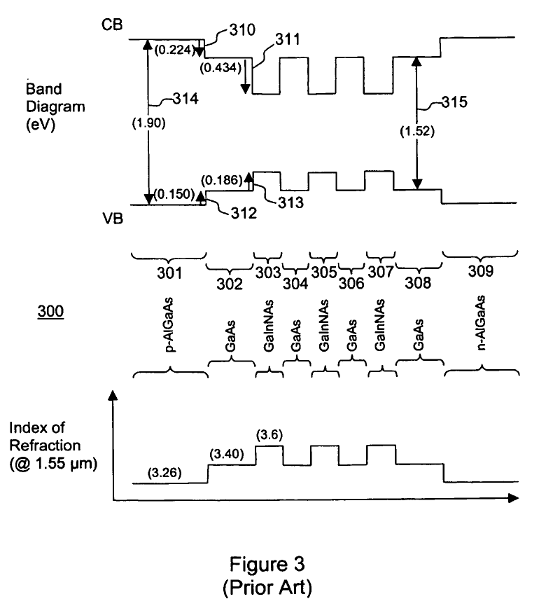

FIG. 4 is a diagram showing the band structure and index of refraction characteristics of a first embodiment of the semiconductor laser structure of the present invention

FIG. 5 is a diagram showing the band structure and index of refraction characteristics of a second embodiment of the semiconductor laser structure of the present invention; and

FIG. 6 is a diagram showing the band structure and index of refraction characteristics of a third embodiment of the semiconductor laser structure of the present invention.

It will be noted that, throughout the appended drawings, like features are identified by like reference numerals

### DETAILED DESCRIPTION OF THE INVENTION

The present invention provides a semiconductor laser structure that can be grown lattice-matched to InP and which opens up the possibility of achieving conduction band energy offsets similar to the InGaNAs/GaAs material system.

One way to improve temperature performance of laser structures using InP based materials, is to use a waveguide cladding material having an index of refraction less than that of InP at the optical wavelengths of interest, and having a bandgap energy greater than that of InP. The present invention uses antimony-based materials such as AlAsSb (aluminum-arsenide-antimonide) as a waveguide cladding. When used in conjunction with active regions and confinement layers containing no antimony, such antimony-based cladding layers present excellent electron confinement and waveguide characteristics. One advantage of these materials is that they can be lattice-matched to InP.

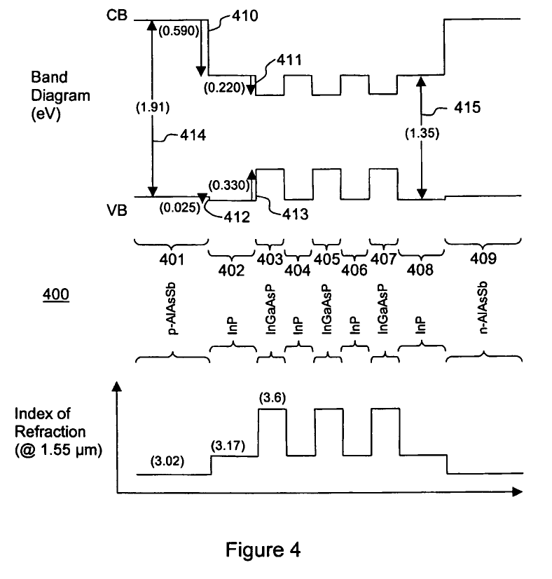

FIG. 4 illustrates a first embodiment of the semiconductor laser structure of the present invention. This laser uses a InP material system traditionally used for telecommunications systems but with novel AlAsSb waveguide cladding layers. Referring to FIG. 4, the laser structure 400 comprises an active region comprising quantum wells 403, 405, 407 of InGaAsP and separated by barrier layers 404, 406 of InP. The active region is bounded by confinement layers 402, 408. The confinement layers 402, 408 are bounded respectively by cladding layer 401 of p-AlAsSb and cladding layer 409 of n-AlAsSb. These layers are deposited on a InP substrate (not shown). Referring to the band diagram of FIG. 4, the conduction band offset 410 between the cladding layers (401, 409) and the confinement layers (402, 408) is 594 meV. The conduction band offset 411 between the confinement and barrier layers (402, 404, 406, 408) and the quantum wells (403, 405, 407) is 220 meV. The valence band offset 412 between the cladding layers (401, 409) and the confinement layers (402, 408) is −25 meV. The valence band offset 413 between the confinement and barrier layers (402, 404, 406, 408) and the quantum wells (403, 405, 407) is 330 meV. Note that in spite of the cladding layers (401, 409) having a band energy higher than the confinement and barrier layers (402, 404, 406, 408), holes are still well confined in the quantum wells (403, 405, 407) because of their high density of states, large effective mass and low mobility, compared to electrons.

The energy bandgap 414 of AlAsSb (401, 409) is 1.91 eV and the energy bandgap 415 of InP (402, 404, 406, 408) is 1.35 eV. Referring now to the index of refraction diagram of FIG. 4, for an optical wavelength of 1.55 μm, the index of refraction of the cladding layers (401, 409) is 3.02, the index of refraction of the barrier layers (402, 404, 406, 408) is 3.17 and the index of refraction of the quantum wells (403, 405, 407) is 3.6. The cladding layer can be considered as an optical cladding layer or a waveguide cladding layer.

The laser structure thus has an active region capable of emitting radiation, the active region is bounded by confinement layers on each side to confine electrons, and the confinement layers are bounded by waveguide cladding layers to further confine electrons and to confine radiation (photons).

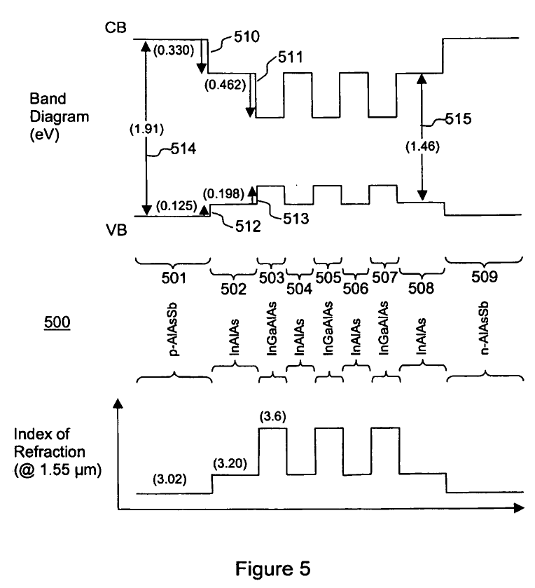

FIG. 5 illustrates a second embodiment of the semiconductor laser structure of the present invention using a newer material system than that of the embodiment of FIG. 4, and exhibits better high temperature performance. This laser uses AlAsSb waveguide cladding layers with InAlAs barriers and InGaAlAs quantum wells. Referring to FIG. 5, the laser structure 500 comprises an active region comprising quantum wells 503, 505, 507 of InGaAlAs, separated by barrier layers 504, 506 of InAlAs. The active region is bounded by confinement layers 502, 508. The confinement layers 502, 508 are bounded respectively by cladding layer 501 of p-AlAsSb and cladding layer 509 of n-AlAsSb. Referring to the band diagram of FIG. 5, the conduction band offset 510 between the cladding layers (501, 509) and the confinement layers (502, 508) is about 334 meV. The conduction band offset 511 between the confinement and barrier layers (502, 504, 506, 508) and the quantum wells (503, 505, 507) is 462 meV. The valence band offset 512 between the cladding layers (501, 509) and the confinement layers (502, 508) is 125 meV. The valence band offset 513 between the confinement and barrier layers (502, 504, 506, 508) and the quantum wells (503, 505, 507) is 198 meV. The energy bandgap 514 of AlAsSb (501, 509) is 1.91 eV and the energy bandgap 515 of InAlAs (502, 504, 506, 508) is 1.46 eV. Referring now to the index of refraction diagram of FIG. 5, for an optical wavelength of 1.55 μm, the index of refraction of the cladding layers (501, 509) is 3.02, the index of refraction of the confinement and barrier layers (502, 504, 506, 508) is 3.20 and the index of refraction of the quantum wells (503, 505, 507) is 3.6.

The confinement layers (502, 508) provide electron confinement. The cladding layers (501, 509) provide additional electron confinement and also help control the electron flow into the quantum wells (503, 505, 507), providing better performance than can be expected from the increase in barrier height alone. The cladding layers (501, 509) also provide optical confinement due to the low index of refraction.

The use of ternary AlAsSb composition as a cladding layer provides excellent high temperature performance. Other embodiments of the present invention use quaternary compositions having small quantities of other elements such as Gallium (Ga) for example, thereby using AlGaAsSb as the cladding layer.

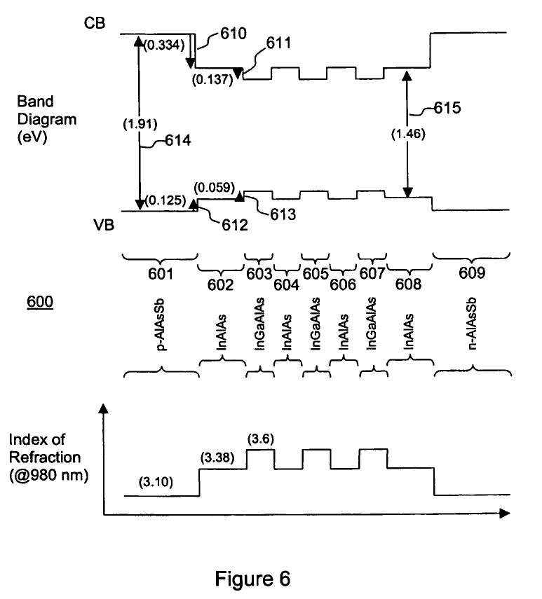

FIG. 6 illustrates a third embodiment of the semiconductor laser structure of the present invention. This embodiment is similar to the second embodiment of FIG. 5 but adapted to operate at a wavelength of 980 nm. Referring now to FIG. 6, the laser structure 600 comprises an active region comprising quantum wells 603, 605, 607 of InGaAlAs separated by barrier layers 604, 606 of InAlAs. The active region is bounded by confinement layers 602, 608. The confinement layers 602, 608 are bounded respectively by cladding layer 601 of p-AlAsSb and cladding layer 609 of n-AlAsSb. Referring to the band diagram of FIG. 6, the conduction band offset 610 between the cladding layers (601, 609) and the confinement layers (602, 608) is about 334 meV. The conduction band offset 611 between the confinement and barrier layers (602, 604, 606, 608) and the quantum wells (603, 605, 607) is 137 meV. The valence band offset 612 between the cladding layers (601, 609) and the confinement layers (602, 608) is 125 meV. The valence band offset 613 between the confinement and barrier layers (602, 604, 606, 608) and the quantum wells (603, 605, 607) is 59 meV. The energy bandgap 614 of AlAsSb (601, 609) is 1.91 eV and the energy bandgap 615 of InAlAs (602, 604, 606, 608) is 1.46 eV. Referring now to the index of refraction diagram of FIG. 6, for an optical wavelength of 980 nm, the index of refraction of the cladding layers (601, 609) is 3.10, the index of refraction of the confinement and barrier layers (602, 604, 606, 608) is 3.38 and the index of refraction of the quantum wells (603, 605, 607) is 3.6.

The embodiment of FIG. 6 illustrates that the present invention is useful at 980 nm in addition to the longer wavelengths (980 nm to 1.55 μm) of typical optical telecommunications systems.

The present invention is applicable to many types of semiconductor laser configurations such as, but not limited to Fabry-Perot pump lasers, distributed feedback (DFB) lasers using gratings and semiconductor optical amplifiers (SOA).

The embodiments of the invention described above are intended to be exemplary only. The scope of the invention is therefore intended to be limited solely by the scope of the appended claims.

1. A semiconductor laser structure comprising:
an active region capable of emitting radiation, said active region being free of antimony;
a confinement layer adjacent said active region, said confinement layer adapted to confine electrons in the active region, said confinement layer being free of antimony; and
a cladding layer adjacent said confinement layer, said cladding layer comprising an antimony-based (Sb) alloy.

2. A semiconductor laser structure as claimed in claim 1, wherein the cladding layer has a lower index of refraction than the confinement layer.

3. A semiconductor laser structure as claimed in claim 2, wherein the cladding layer is an optical waveguide cladding layer.

4. A semiconductor laser structure as claimed in claim 2, wherein the cladding layer has a larger bandgap than the confinement layer.

5. A semiconductor laser structure as claimed in claim 4, wherein the cladding layer is lattice-matched to InP.

6. A semiconductor laser structure as claimed in claim 5, wherein the cladding layer comprises AlAsSb.

7. A semiconductor laser structure as claimed in claim 5, wherein the cladding layer comprises a compound comprising predominantly Al, As and Sb.

8. A semiconductor laser structure as claimed in claim 7, wherein the cladding layer comprises AlGaAsSb.

9. A semiconductor laser structure as claimed in claim 6, wherein the active region comprises at least one quantum well.

10. A semiconductor laser structure as claimed in claim 9, wherein the active region comprises a plurality of quantum wells separated by barrier layers.

11. A semiconductor laser structure as claimed in claim 10, wherein the barrier layers comprise the same material as said confinement layer.

12. A semiconductor laser structure as claimed in claim 9, wherein the at least one quantum well comprises InGaAsP.

13. A semiconductor laser structure as claimed in claim 12, wherein the confinement layer comprises InP.

14. A semiconductor laser structure as claimed in claim 9, wherein the at least one quantum well comprises InGaAlAs.

15. A semiconductor laser structure as claimed in claim 14, wherein the confinement layer comprises InAlAs.

16. A device selected from the group comprising a Fabry-Perot laser, a distributed feedback (DFB) laser and a semiconductor optical amplifier (SOA) wherein the device comprises a semiconductor laser structure as claimed in claim 6.

17. A semiconductor laser structure comprising:
an active region having a first side and a second side, said active region being capable of emitting radiation, said active region being free of antimony;
a first confinement layer adjacent said first side of said active region, said first confinement layer adapted to confine electrons in the active region, said first confinement layer being free of antimony;
a second confinement layer adjacent said second side of said active region, said second confinement layer adapted to confine electrons in the active region, said second confinement layer being free of antimony;
a first cladding layer adjacent said first confinement layer, said first cladding layer comprising an antimony-based (Sb) alloy; and
a second cladding layer adjacent said second confinement layer, said second cladding layer comprising an antimony-based (Sb) alloy.

18. A semiconductor laser structure as claimed in claim 17, wherein said first confinement layer and second confinement layer cooperate to confine electrons in the active region.

19. A semiconductor laser structure as claimed in claim 18, wherein said first cladding layer and said second cladding layer are adapted to confine electrons in the active region.

20. A semiconductor laser structure as claimed in claim 18, wherein said first cladding layer and said second cladding layer are adapted to confine photons in the active region.

21. A semiconductor laser structure as claimed in claim 19, wherein said first cladding layer and said second cladding layer are adapted to confine photons in the active region.

22. A semiconductor laser structure as claimed in claim 19, wherein said first cladding layer and said second cladding layer are adapted to cooperate with said first confinement layer and said second confinement layer to confine electrons in the active region.

23. A semiconductor laser structure as claimed in claim 21, wherein said first cladding layer and said second cladding layer are lattice-matched to InP.

24. A semiconductor laser structure as claimed in claim 21, wherein said first cladding layer and said second cladding layer comprise AlAsSb.

25. A semiconductor laser structure as claimed in claim 21, wherein said first cladding layer and said second cladding layer comprise a compound comprising predominantly Al, As and Sb.

26. A semiconductor laser structure as claimed in claim 25, wherein said first cladding layer and said second cladding layer comprise AlGaAsSb.

27. A semiconductor laser structure as claimed in claim 25, wherein said active region comprises at least one quantum well.

28. A semiconductor laser structure as claimed in claim 25, wherein said first confinement layer and said second confinement layer comprise InP.

29. A semiconductor laser structure as claimed in claim 27, wherein said first confinement layer and said second confinement layer comprise InP.

30. A semiconductor laser structure as claimed in claim 29, wherein said at least one quantum well comprises InGaAsP.

31. A semiconductor laser structure as claimed in claim 27, wherein said first confinement layer and said second confinement layer comprise InAlAs.

32. A semiconductor laser structure as claimed in claim 31, wherein said at least one quantum well comprises InGaAlAs.

33. A semiconductor laser structure based on an InP material system, the laser structure comprising:
an active region capable of emitting radiation;
a confinement layer adjacent said active region, said confinement layer adapted to confine electrons in the active region; and
a cladding layer adjacent said confinement layer, said cladding layer comprising an antimony-based (Sb) alloy.

34. A semiconductor laser structure as claimed in claim 33, wherein the cladding layer is an optical waveguide cladding layer.

35. A semiconductor laser structure as claimed in claim 34, wherein the cladding layer has a lower index of refraction than the confinement layer.

36. A semiconductor laser structure as claimed in claim 35, wherein the cladding layer has a larger bandgap than the confinement layer.

37. A semiconductor laser structure as claimed in claim 36, wherein the cladding layer is lattice-matched to InP.

38. A semiconductor laser structure as claimed in claim 37, wherein the cladding layer comprises a compound comprising predominantly Al, As and Sb.

39. A semiconductor laser structure as claimed in claim 38, wherein the cladding layer comprises AlAsSb.

40. A semiconductor laser structure as claimed in claim 38, wherein the cladding layer comprises AlGaAsSb.

41. A semiconductor laser structure as claimed in claim 38, wherein the active region comprises at least one quantum well.

42. A semiconductor laser structure as claimed in claim 41, wherein the active region comprises a plurality of quantum wells separated by barrier layers.

43. A semiconductor laser structure as claimed in claim 42, wherein the barrier layers comprise the same material as said confinement layer.

44. A semiconductor laser structure as claimed in claim 41, wherein the at least one quantum well comprises InGaAsP.

45. A semiconductor laser structure as claimed in claim 44, wherein the confinement layer comprises InP.

46. A semiconductor laser structure as claimed in claim 41, wherein the at least one quantum well comprises InGaAlAs.

47. A semiconductor laser structure as claimed in claim 46, wherein the confinement layer comprises InAlAs.

48. A device selected from the group comprising a Fabry-Perot laser, a distributed feedback (DFB) laser and a semiconductor optical amplifier (SOA) wherein the device comprises a semiconductor laser structure as claimed in claim 38.
